(19) United States
(12) Patent Application Publication
(10) Pub. No.: US 2012/0009334 A1
(43) Pub. Date: Jan. 12, 2012

(54) Method of Fabricating One-Dimensional Nanostructure of Organo-Optoelectronic Material

(75) Inventors: Tu Lee, New York, NY (US); Ming-Shiou Lin, Kaohsiung County (TW)

(73) Assignee: NATIONAL CENTRAL UNIVERSITY, Taoyuan County (TW)

(21) Appl. No.: 13/243,057

(22) Filed: Sep. 23, 2011

Related U.S. Application Data
(63) Continuation-in-part of application No. 12/068,241, filed on Feb. 4, 2008.

(30) Foreign Application Priority Data
Aug. 9, 2007 (TW) 096129462

(51) Int. Cl. B05D 5/06; B05D 5/12; B05D 3/02; B05D 3/10; C23C 14/34; B05D 3/00; B82Y 40/00

(52) U.S. Cl. 427/66; 204/192.1; 977/891

(57) ABSTRACT

An organo-optoelectronic nanowire is fabricated. It is made through a one-step unit operation under a low temperature. An organo-optoelectronic template is obtained for the fabrication, whose idea is a bio-inspired one. The nanowire obtained has a high efficiency and a high surface area; and, heat generated on operation is easily emitted. Thus, the method has great potential for future use on optoelectronic devices.

### CROSS-REFERENCE TO RELATED APPLICATION

This application is a continuation-in-part of U.S. Ser. No. 12/068,241 filed on Feb. 4, 2008, entitled “Method of Fabricating One-Dimensional Nanostructure of Organo-Optoelectronic Material,” the disclosure of which is incorporated herein by reference in its entirety.

### FIELD OF THE INVENTION

The present invention relates to fabricating an organo-optoelectronic nanowire; more particularly, relates to obtaining a nanowire with an organo-optoelectronic template through a one-step unit operation under a low temperature.

### DESCRIPTION OF THE RELATED ARTS

Organic electroluminescent devices are widely applicable with self-luminescence, and provide a wide view angle, saved power, low cost, high responsibility and full color gamut. And an organic electroluminescent material is critical for the device.

Methods for fabricating a nanowire of the organic electroluminescent material include chemical preparations, redox reactions, hydrothermal processes, spray-drying methods, sol-gel methods, emulsion methods, electrolysis methods and chemical vapor deposition (CVD) methods, where the CVD methods are the most widely used.

CVD obtains a film or tiny particles of a solid-state material with a gas or gases through a chemical reaction. A metal substrate is obtained, and a catalyst is coated on the substrate through ion sputtering with a powder of iron, aluminum or nickel. Therein, a plate is put in a horizontal tubular oven. Two refractories are obtained separately with the metal powder and the metal substrate put upon. The refractory with the metal powder is put at a co-current position corresponding to the refractory with the metal substrate. With an inert gas (like argon) filled-in, the metal substrate is prevented from oxidation. Then the horizontal tubular oven is heated to a high temperature to grow a metal material at a nano-scale. After the chemical reaction is finished, the temperature is lowered to a room temperature. Thus, a metal nanowire is obtained through CVD.

Although the prior arts fabricate nanowires, procedures related are complex, such as that both a substrate and a catalyst have to be prepared. Besides, their outputs are not effective enough and their costs are also high. Hence, the prior arts do not fulfill all users' requests on actual use.

### SUMMARY OF THE INVENTION

The main purpose of the present invention is to fabricate nanowires with an organo-optoelectronic template through a one-step unit operation under a low temperature.

To achieve the above purpose, the present invention is a method of fabricating a one-dimensional nanostructure of an organo-optoelectronic material, comprising steps of: (a) obtaining a fresh egg shell to be rinsed with a deionized water and, after being fully immersed in the deionized water for a period of time, removing a biological tissue from the egg shell to be vacuum-dried in a vacuum oven; (b) immersing a gold-coated wafer in an alcohol solution having 1-Undecanethiol (1-UDT) and 11-Mercaptoundecanoic acid (11-MUA) and taking out the wafer to be dried with a nitrogen gas for obtaining a self-assembly monolayer; and (c) obtaining a template comprised of the biological tissue and the self-assembly monolayer and spin cast films of soluble eggshell membrane solution processing a deposition on the template with powders of tris(8-hydroxyquinolato)aluminum (Alq3) or other organic compounds in an evaporation screening device (e.g., an evacuation chamber) under a controlled temperature to obtain an Alq3 nanowire, where the evaporation screening device comprises a ceramics hot plate as a heat source; an aluminum mass deposed on the ceramics hot plate, which has arrays of holes; a plurality of glass tubes inserted into the holes of the aluminum mass separately; and a plurality of stainless steel tubes inserted into the glass tubes separately. Accordingly, a novel method of fabricating a one-dimensional nanostructure of an organo-optoelectronic material is obtained.

### BRIEF DESCRIPTION OF THE DRAWING

The present invention will be better understood from the following detailed description of the preferred embodiment according to the present invention, taken in conjunction with the accompanying drawing, in which

FIG. 1 is the flow view showing the preferred embodiment according to the present invention.

### DESCRIPTION OF THE PREFERRED EMBODIMENT

The following description of the preferred embodiment is provided to understand the features and the structures of the present invention.

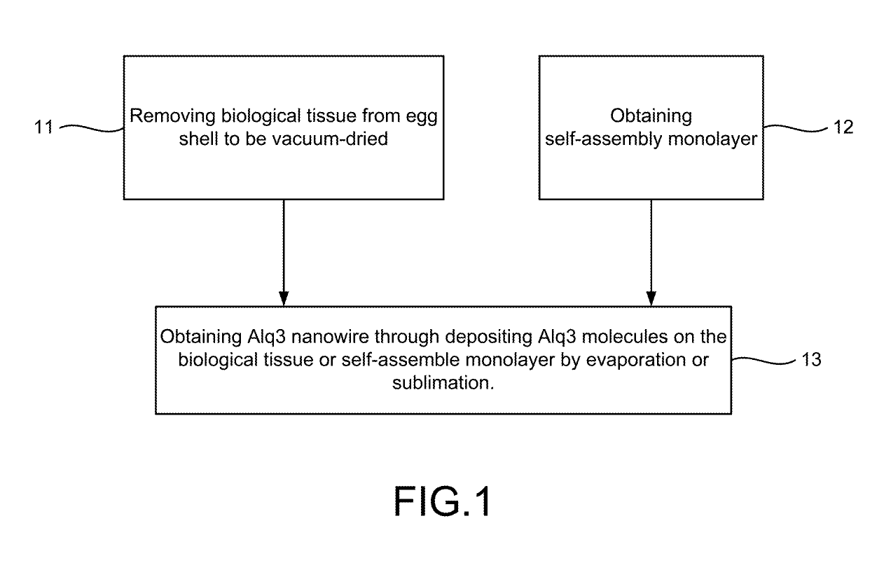

Please refer to FIG. 1, which is a flow view showing a preferred embodiment according to the present invention. As shown in the FIGURE, the present invention is a method of fabricating a one-dimensional nanostructure of an organo-optoelectronic material, comprising the following steps:

(a) Removing biological tissue from egg shell to be vacuum-dried 11: A fresh egg shell is obtained. The egg shell can be refrigerated to keep it from being spoiled or chemically altered. The egg shell is then rinsed with deionized water and then is immersed in deionized water for a time long enough to separate all or part of the egg membrane from the egg shell. The time can be from about 10 minutes to 6 hours, including, but not limited to 20 minutes, half an hour, 45 minutes, 1 hour, 1.5 hours, 2 hours, 3 hours, 4 hours, and 5 hours without exception. Immersing the egg shell in the deionized water is a gentle way of allowing for the separation of the all or part of the egg membrane from the egg shell. All or part of the egg membrane constitutes the biological tissue. Then the biological tissue is removed from the egg shell into a vacuum oven and is vacuum-dried in the vacuum oven at a temperature of between about 24 and 35° Celcius, including but not limited to, 25, 26, 27, 28, 29, 30, 31, 32, 33, and 34 Celsius degrees (° C.) for 3 to 8 hours (hr), where the biological tissue is all or part of an egg membrane.

The egg membrane provides functional groups which can be used to graft onto self-assemble molecules (SAMs). Thus, the egg membrane provides a biomaterial template to identify functional groups. The functional groups can then be used to chemically synthesize onto SAMs. Then the functionalized SAM monolayer can be attached to the gold-coated wafer.

The functional groups on the eggshell membrane can be identified by X-ray photoelectron spectroscopy (XPS) and attenuated total reflectance Fourier transform infrared spectroscopy (ATR-FTIR). Nano-regions of the functional groups can then be used to serve a nucleation centers for the nanowires. Typically, the functional groups are pendent groups of the amino acids existing in the eggshell membrane.

(b) Obtaining self-assembly monolayer (SAM) 12: An alcohol solution having 1-Undecanethiol (1-UDT) and 11-Mercaptoundecanoic acid (11-MUA) is obtained, where the 1-UDT and the 11-MUA have a molar ratio of 1:1. A wafer coated with gold is immersed in the alcohol solution. After 48 hrs, the wafer is taken out to be dried with a nitrogen gas and thus a self-assembly monolayer (SAM) is obtained.

(c) Obtaining an Alq3 nanowire through hot-drying 13: A template comprised of the biological tissue and the self-assembly monolayer is processed through a deposition with a powder of tris(8-hydroxyquinolato)aluminum (Alq3). The deposition occurs in an evaporation screening device (an evacuation chamber) under a controlled temperature. The temperature can be between 270 and 290° C., including but not limited to, 270, 275, 280, 285, and 290° C. The evaporation can occur for a time of between about 20 minutes and 45 minutes, including but not limited to, 25 minutes, half an hour, 35 minutes, and 40 minutes. The evaporation can occur with a vacuum of between about 6.6 and 6.8×10⁻² pascal, including 6.7×10⁻² pascal for long enough to obtain an Alq3 nanowire. Therein, the Alq3 is a chelate of a hydroxyquinolinate and aluminum, which has a good electroluminescence; and, the Alq3 nanowire thus obtained is able to emit a green light having a range of wavelength around 530 nanometers (nm).

The eggshell membrane or the wafer with SAMS provide a surface for any gaseous species (for example by thermal evaporation in a vacuum chamber where powder Alg3 would become gaseous Alq3, or solutes (for example by hydrothermal processes in a beaker) to nucleate onto it to form nanowires. Therefore, the eggshell membrane and the wafer with SAMs could be a stand-alone device for nucleation or they could be integrated into a manufacturing process to become a processing step or even to become part of the device as a buffer layer.

The evaporation screening device comprises a ceramics hot plate as a heat source; an aluminum mass on the ceramics hot plate, which has arrays of holes; a plurality of glass tubes inserted into the holes of the aluminum mass separately; and a plurality of stainless steel tubes inserted into the glass tube separately, each of which has a plate. And the evaporation screening device is connected with a vacuum pump. Thus, the evaporation screening device can be used to screen a few templates on a plurality of plates of the stainless steel tubes with a few materials evaporated.

On using the present invention, a one-step unit operation under a low temperature is used for fabricating the nanowire of an organo-optoelectronic material. Non-organic crystal may be found in living creature whose growth and arrangement are controlled through an organic layer. The present invention is thus inspired that the template of the organo-optoelectronic materials, comprising the biological tissue (i.e. egg membrane) and the self-assembly monolayer, is obtained for the Alq3 nanowire through a special group of the egg membrane. Therein, application of the self-assembly monolayer on the organic electroluminescent device increases efficiency and contact area; reduces destruction from humidity; and prolongs component stability and life time. And the induction of a conductive nano-structure is controlled and boundary of the nano-structure is screened.

Concerning the growth of the Alq3 nanowire, an X-ray electron spectrum for chemical analysis (ESCA) is used to analyze the self-assembly monolayer. Hence, it is proved that a compositive ratio on a wafer surface is selective and is not equal to a density ratio of the alcohol solution. Hence, the self-assembly monolayer simulates functional arrays to obtain a mechanism for growing nanowire. Besides, through a photoluminescence (PL) diagram of the Alq3 nanowire, it is found that the Alq3 nanowire has a higher strength and red-shift. Through a high efficiency and a high surface area, heat emission during operation can be enhanced. Hence, both with a low operating temperature and a one-step unit operation, the present invention is widely applicable.

To sum up, the present invention is a method of fabricating a one-dimensional nanostructure of an organo-optoelectronic material, where nanowires of an organo-optoelectronic material is fabricated through a one-step unit operation with a bio-inspired template; through a high efficiency and a high surface area, heat emission generated on operation is enhanced; and, both with a low operating temperature and a one-step unit operation, the present invention is widely applicable.

### Example

In the laboratory, one sample at a time was prepared. Commercial hens eggs were gently broken and emptied. The eggshells were rinsed with water. The outer shell membrane (OSM) was manually removed from the shell, rinsed with water and oven dried at 30° C. overnight. The resulting dehydrated unboiled OSM was used as a template for the thermal evaporation of Alq3.

About 0.6 g of the dehydrated OSM was dissolved in 20 mL of 1.25 mol/L aqueous 3-mercaptopropionic acid in the present of 10% acetic acid at 90° C. for 12 hours. The OSM solution was cast on a 1×1 cm² glass substrate and oven dried at 40° C. overnight. The dried film was then rinsed with copious amounts of methanol.

About 20 mg of the commercial Alq3 was placed at the bottom of a 20 cm long Pyrex glass tube with an inner diameter of 2.0 cm. The bottom of the tube was inserted vertically in an aluminum heating block and the lateral surface of the tube was insulated with glass wool. The wafer with SAMS (face down) or the eggshell membrane was located about 3 cm above the tube bottom and kept at about 138° C. Thermal evaporation of Alq3 was performed at 280° C. and under 6.7×10⁻² Pa maintained by a vacuum pump (GVD-050A, ULVAC KIKO, Inc., Japan). Regular sample preparation time was 10 min. The method obtained nanowires that were essentially grown in one dimension—lengthwise.

In other embodiments, the method could be performed in multiples and/or the wafers (or egg membranes) overlapped and the Pyrex tube could be replaced with a chamber with more working space such as a chemical vapor deposition (CVD) device.

Methods for producing nanowires from the eggshell membrane are provided in Lee et al., 2010, Thin Solid Films 518, pp. 5488-5493, herein incorporated by reference in its entirety.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of fabricating a nanowire of an organo-optoelectronic material, comprising the steps of:
(a) obtaining an egg shell to be washed with deionized water and, after being fully immersed in said deionized water for a period of time, removing the egg membrane from said egg shell to be vacuum-dried in a vacuum oven;
(b) immersing a gold-coated wafer in an alcohol solution having 1-Undecanethiol (1-UDT) and 11-Mercaptoundecanoic acid (11-MUA) and taking out said wafer to obtain a self-assembly monolayer by being dried with a nitrogen gas; and
(c) placing said egg membrane and said self-assembly monolayer into a vacuum device and processing a deposition on said SAM with a powder of tris(8-hydroxyquinolato)aluminum(III) (Alq3) in an evaporation screening device under a controlled temperature to obtain an Alq3 nanowire.

2. The method according to claim 1,
wherein said egg shell is immersed in said deionized water half an hour.

3. The method according to claim 1,
wherein said egg membrane is immersed in deionized water for a period of time necessary to peel the egg membrane from the egg shell.

4. The method according to claim 1,
wherein said egg membrane is dried in said vacuum oven under a temperature of 30 Celsius degrees (° C.) for 3 to 8 hours (hr).

5. The method according to claim 1,
wherein said 1-UDT and said 11-MUA have a mole ratio of 1:1.

6. The method according to claim 1,
wherein said wafer is immersed for 48 hrs.

7. The method according to claim 1,
wherein said deposition in said evaporation screening device is processed half an hour under 280° C. with a vacuum of 6.7×10⁻² pascal.

8. The method according to claim 1,
wherein said controlled temperature is 60° C.

9. The method according to claim 1,
wherein said vacuum device is an evaporation screening device comprising:
a ceramics hot plate, said ceramic hot plate heat source;
an aluminum mass, said aluminum mass being deposed on said ceramics hot plate, said aluminum mass having holes;
a plurality of glass tubes, each of said glass tube being inserted into a hole of said aluminum mass; and
a plurality of stainless steel tubes, each of said stainless steel tubes being inserted into said glass tube.

10. The method according to claim 9,
wherein said stainless steel tube is hollow.

11. The method according to claim 9,
wherein said stainless steel tube has a plate.

12. The method according to claim 9,
wherein said evaporation screening device is connected with a vacuum pump.

13. The method according to claim 1, further comprising dissolving the dried membrane in a dilute acid mixture and casting on the gold-coated wafer and oven drying overnight.
